(19) United States
(12) Patent Application Publication
(10) Pub. No.: US 2026/0305033 A1
(43) Pub. Date: Oct. 1, 2026

(54) DISPLAY DEVICE

(71) Applicants: LG ELECTRONICS INC., Seoul (KR); LG DISPLAY CO., LTD., Seoul (KR)

(72) Inventors: Jaewon CHANG, Seoul (KR); Dohan KIM, Seoul (KR); Sungmin PARK, Seoul (KR)

(73) Assignees: LG ELECTRONICS INC., Seoul (KR); LG DISPLAY CO., LTD., Seoul (KR)

(21) Appl. No.: 18/879,635

(22) PCT Filed: Jun. 27, 2022
(86) PCT No.: PCT/KR2022/009149

§ 371 Date: Dec. 27, 2024

(51) Int. Cl. H10H 29/49; H10H 29/39

(52) U.S. Cl. CPC H10H 29/49; H10H 29/39

(57) ABSTRACT

A display device includes a substrate including a sub-pixel, a first assembly wiring disposed along one direction on the substrate, a second assembly wiring disposed parallel to the first assembly wiring, a barrier wall disposed on the first assembly wiring and the second assembly wiring and including a first hole in the sub-pixel, and a semiconductor light emitting device in the first hole. The second assembly wiring can surround a portion of the first assembly wiring. The portion of the first assembly wiring and the second assembly wiring have a predetermined gap in an edge area of the first hole.

### TECHNICAL FIELD

The embodiment relates to a display device.

### BACKGROUND ART

Large-area displays include liquid crystal displays (LCDs), OLED displays, and micro-LED displays.

Micro-LED displays are displays that use micro-LEDs, semiconductor light emitting devices with a diameter or cross-sectional area of 100 μm or less, as display devices.

Micro-LED displays have excellent performance in many characteristics such as contrast ratio, response speed, color reproducibility, viewing angle, brightness, resolution, lifespan, luminous efficiency, and brightness because they use micro-LEDs, semiconductor light emitting devices, as display devices.

In particular, micro-LED displays have the advantage of being able to freely adjust the size and resolution by separating and combining the screen in a modular manner, and the advantage of being able to implement a flexible display.

However, since large micro-LED displays require millions of micro-LEDs, there is a technical problem that makes it difficult to quickly and accurately transfer micro-LEDs to the display panel.

Transfer technologies that are being developed recently include the pick and place process, the laser lift-off method, or the self-assembly method.

Among these, the self-assembly method is a method in which semiconductor light emitting devices find their own assembly positions in a fluid, and is advantageous for implementing large-screen display devices.

However, research on the technology for manufacturing displays through the self-assembly of micro-LEDs is still insufficient.

In particular, in the case of rapidly transferring millions or more semiconductor light emitting devices to a large display in the prior art, the transfer speed can be improved, but there is a technical problem that the transfer error rate can increase and the transfer yield can be reduced.

In the related technology, a self-assembly transfer process using dielectrophoresis (DEP) is being attempted, but there is a problem that the self-assembly rate is low due to the non-uniformity of the DEP force.

FIG. 1 illustrates the structure of an assembly wiring for assembling a semiconductor light emitting device according to a non-public internal technology.

As shown in FIG. 1A, the first assembly wiring 2 and the second assembly wiring 3 are disposed in parallel, and semiconductor light is emitted in the assembly hole 5H on these assembly wirings 2 and 3. The element 6 is assembled.

That is, as illustrated in FIG. 2A, a DEP force is formed between the first assembly wiring 2 and the second assembly wiring 3, and the semiconductor light emitting device 6 is pulled by this DEP force and inserted into the assembly hole 5H.

The DEP force is largest at the gap between the end of the first assembly wiring 2 and the end of the second assembly wiring 3 facing each other, and the DEP force decreases as it gets farther away from the end of the first assembly wiring 2 or the end of the second assembly wiring 3. In other words, the DEP force is large in the center area of the assembly hole 5H along the X-axis direction, and small in the edge area of the assembly hole 5H, so that the DEP force is non-uniform. In addition, the gap between the first assembly wiring 2 and the second assembly wiring 3 is very small compared to the diameter of the semiconductor light emitting device 6. In particular, the gap between the first assembly wiring 2 and the second assembly wiring 3 is positioned along the center line 8 of the semiconductor light emitting device 6 in the same direction as the Y-axis direction.

Therefore, since the DEP force is non-uniform along the X-axis direction within the assembly hole 5H and is strong only along the center line 8 of the semiconductor light emitting device 6 along the Y-axis direction, the semiconductor light emitting device 6 cannot be stably assembled into the assembly hole 5H. That is, since the DEP force does not act on the edge area of the semiconductor light emitting device 6, a defect occurs in which the semiconductor light emitting device 6 is assembled in a twisted or tilted state (FIG. 2B).

In addition, even if the semiconductor light emitting device 6 is assembled into the assembly hole 5H, since the DEP force does not act on the edge area of the semiconductor light emitting device 6, there is a problem in which the semiconductor light emitting device 6 is not fixed within the assembly hole 5H and is detached.

Meanwhile, the unexplained symbol 1 is a substrate, and 4 is an insulating layer.

### DISCLOSURE

### Technical Problem

The object of embodiment is to solve the above-mentioned problems and other problems.

Another object of the embodiment is to provide a display device capable of preventing assembly failure.

In addition, another object of the embodiment is to provide a display device capable of preventing detachment of an assembled semiconductor light emitting device.

The technical objects of the embodiment are not limited to those described in this article, and include those that can be understood through the description of the invention.

### Technical Solution

According to one aspect of the embodiment to achieve the above or other purposes, the display device includes a substrate including a sub-pixel; a first assembly wiring disposed along one direction on the substrate; a second assembly wiring disposed parallel to the first assembly wiring; a barrier wall disposed on the first assembly wiring and the second assembly wiring and including a first hole in the sub-pixel; and a semiconductor light emitting device in the first hole.

The second assembly wiring surrounds a portion of the first assembly wiring, and the portion of the first assembly wiring and the second assembly wiring have a predetermined gap in an edge area of the first hole.

The gap may be located along an edge area below the semiconductor light emitting device.

The display device may include an insulating layer on the first assembly wiring. The second assembly wiring may be disposed on the insulating layer.

The second assembly wiring may include a main electrode; and the auxiliary electrode extending from the main electrode in the sub-pixel may include; The auxiliary electrode may include a second hole having a diameter smaller than the diameter of the first hole.

The second hole may have a shape corresponding to the shape of the semiconductor light emitting device.

The first assembly wiring may include a main electrode; and a protruding electrode in the second hole of the auxiliary electrode.

The protruding electrode may be connected to the main electrode through the insulating layer.

The auxiliary electrode may surround the protruding electrode.

The diameter of the protruding electrode may be smaller than the diameter of the semiconductor light emitting device.

The protruding electrode and the auxiliary electrode may have the gap, and the gap may be positioned along the edge area of the lower side of the semiconductor light emitting device.

The protruding electrode may include the same metal as the second assembly wiring.

The first assembly wiring may include a bending portion extending from the main electrode toward the second assembly wiring in the pixel area.

The protruding electrode may be connected to the bending portion through the insulating layer.

The width of the bending portion may be smaller than the width of the main electrode.

The width of the bending portion may be smaller than the diameter of the first hole.

The width of the bending portion may be larger than the diameter of the protruding electrode.

The display device may include a connection electrode surrounding the semiconductor light emitting device within the first hole; and an electrode wiring on the semiconductor light emitting device. The connection electrode may be connected to at least one of the first assembly wiring or the second assembly wiring.

### Advantageous Effects

As illustrated in FIGS. 9 and 10, a first hole 340H for assembling a semiconductor light emitting device 150 may be provided in a sub-pixel (PX). The second assembly wiring 322 may include an auxiliary electrode 322-2 including a second hole 320H having a diameter (D2) smaller than a diameter (D1) of the first hole 340H within the first hole 340H. At this time, a protruding electrode 321-3 of the first assembly wiring 321 may be vertically protruded and placed in the second hole 320H of the auxiliary electrode 322-2. In this case, a predetermined gap (G1) may be formed between the protruding electrode 321-3 and the auxiliary electrode 322-2. The gap (G1) may be formed along an edge area of the first hole 340H. That is, the gap (G1) can be formed along the circumference of the protruding electrode 321-3.

When an AC voltage is applied to the first assembly wiring 321 and the second assembly wiring 322 for self-assembly, the largest DEP force can be formed in the gap G1. In this case, the semiconductor light emitting device 150 can be pulled into the first hole (34H) by the DEP force, and also, since the largest DEP force is applied along the lower edge area of the semiconductor light emitting device 150 inserted into the first hole 340H, the semiconductor light emitting device 150 can be stably settled without being twisted or tilted toward the bottom of the first hole 340H, that is, the upper surface of the second insulating layer 335. In addition, since the largest DEP force is continuously applied along the edge area on the lower side of the semiconductor light emitting device 150 even after the semiconductor light emitting device 150 is settled in the first hole 340H, the settled semiconductor light emitting device 150 can be firmly fixed within the first hole 340H without falling out of the first hole 340H. Accordingly, assembly defects, such as the semiconductor light emitting device 150 being settled in a twisted or tilted state within the first hole 340H or falling out after being assembled to the first hole 340H, can be prevented, and the assembly yield can be dramatically improved.

Meanwhile, as shown in FIG. 18 and FIG. 19, the bending portion 321-4 extended from the first assembly wiring 321 is disposed in the sub-pixel (PX′), thereby reducing the vertical overlapping area between the first assembly wiring 321 and the second assembly wiring 322, and thus the capacity of the parasitic capacitance can be reduced. As the capacity of the parasitic capacitance is reduced, the loss caused by the parasitic capacitance of the AC voltage between the first assembly wiring 321 and the second assembly wiring 322 can be reduced. Accordingly, a sufficiently large DEP force can be formed even with a smaller AC voltage, and thus the power consumption can be reduced.

Additional scopes of the applicability of the embodiments will become apparent from the detailed description below. However, since various changes and modifications within the spirit and scope of the embodiments can be clearly understood by those skilled in the art, it should be understood that the detailed description and specific embodiments, such as preferred embodiments, are given only as examples.

### DESCRIPTION OF DRAWINGS

FIG. 1 illustrates the structure of an assembly wiring for assembling a semiconductor light emitting device according to a non-disclosed internal technology.

FIG. 2a illustrates a semiconductor light emitting device being assembled in an assembly hole during self-assembly using an assembly wiring structure according to a non-disclosed internal technology.

FIG. 2b illustrates an assembly defect of a semiconductor light emitting device during self-assembly using an assembly wiring structure according to a non-disclosed internal technology.

FIG. 3 illustrates a living room of a house in which a display device according to an embodiment is placed.

FIG. 4 is a block diagram schematically illustrating a display device according to an embodiment.

FIG. 5 is a circuit diagram illustrating an example of a pixel of FIG. 4.

FIG. 6 is an enlarged view of a first panel area in the display device of FIG. 3.

FIG. 7 is an enlarged view of an area A2 of FIG. 6.

FIG. 8 is a drawing illustrating an example in which a light emitting device according to an embodiment is assembled on a substrate by a self-assembly method.

FIG. 9 is a plan view illustrating a sub-pixel according to the first embodiment.

FIG. 10 is a cross-sectional view taken along the C1-C2 line of FIG. 9.

FIG. 11a is a plan view illustrating a state in which a DEP force is formed between a protruding electrode of a first assembly wiring and an auxiliary electrode of a second assembly wiring in a sub-pixel according to the first embodiment.

FIG. 11b is a cross-sectional view illustrating a state in which a semiconductor light emitting device is assembled by a DEP force formed between a protruding electrode of a first assembly wiring and an auxiliary electrode of a second assembly wiring in a sub-pixel according to the first embodiment.

FIG. 12 is a cross-sectional view illustrating a state in which a semiconductor light emitting device is assembled by a DEP force formed between a protruding electrode of a first assembly wiring and an auxiliary electrode of a second assembly wiring in a sub-pixel according to the first embodiment.

FIGS. 13a and 13b illustrate a state in which a first assembly wiring is formed.

FIGS. 14a and 14b illustrate the formation of the second assembly wiring.

FIGS. 15a and 15b illustrate the assembly of a semiconductor light emitting device using DEP force between the first assembly wiring and the second assembly wiring.

FIG. 16 illustrates the post-process for electrical connection of the semiconductor light emitting device.

FIG. 17 is a plan view illustrating a display device according to the first embodiment.

FIG. 18 is a plan view illustrating a sub-pixel according to the second embodiment.

FIG. 19 is a cross-sectional view taken along the line D1-D2 of FIG. 18.

The sizes, shapes, and numbers of the components illustrated in the drawings may differ from the actual ones. In addition, even if the same components are illustrated with different sizes, shapes, and numbers between the drawings, this is only an example in the drawings, and the same components may have the same sizes, shapes, and numbers between the drawings.

### MODE FOR INVENTION

Hereinafter, the embodiments disclosed in this specification will be described in detail with reference to the attached drawings, and regardless of the drawing symbols, identical or similar components will be given the same reference numerals and redundant descriptions thereof will be omitted. The suffixes ‘module’ and ‘part’ used for components in the following description are given or used interchangeably in consideration of the ease of writing the specification, and do not have distinct meanings or roles in themselves. In addition, the attached drawings are intended to facilitate easy understanding of the embodiments disclosed in this specification, and the technical ideas disclosed in this specification are not limited by the attached drawings. In addition, when an element such as a layer, region, or substrate is mentioned as existing ‘on’ another element, this includes that it may be directly on the other element or that other intermediate elements may exist between them.

The display devices described in this specification may include TVs, signage, mobile phones, smart phones, HUDs (head-up displays) for automobiles, backlight units for laptop computers, displays for VR or AR, etc. However, the configuration according to the embodiment described in this specification can also be applied to a new product type developed in the future, or to a device capable of display.

The following describes a light emitting device and a display device including the same according to an embodiment.

FIG. 3 illustrates a living room of a house in which a display device according to an embodiment is disposed.

Referring to FIG. 3, the display device 100 according to the embodiment can display the status of various electronic products such as a washing machine 101, a robot vacuum cleaner 102, and an air purifier (103), and can communicate with each electronic product based on IOT, and can also control each electronic product based on user setting data.

The display device 100 according to the embodiment can include a flexible display manufactured on a thin and flexible substrate. The flexible display can be bent or rolled like paper while maintaining the characteristics of a conventional flat panel display.

In the flexible display, visual information can be implemented by independently controlling the light emission of unit pixels disposed in a matrix form. A unit pixel means the minimum unit for implementing one color. A unit pixel of a flexible display can be implemented by a light emitting device. In an embodiment, the light emitting device may be a Micro-LED or a Nano-LED, but is not limited thereto.

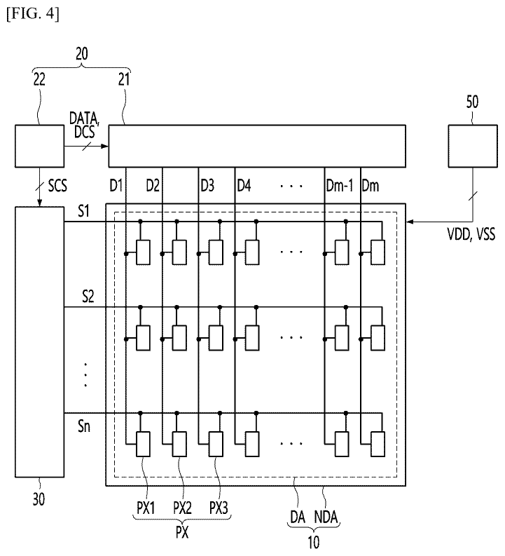

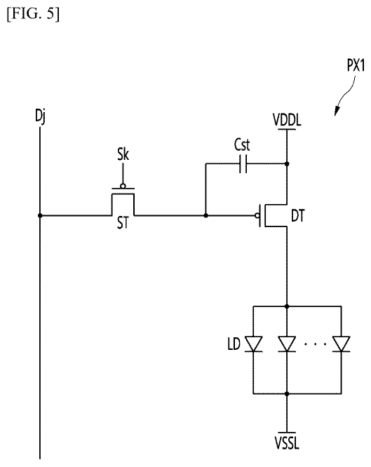

FIG. 4 is a block diagram schematically showing a display device according to an embodiment, and FIG. 5 is a circuit diagram showing an example of a pixel of FIG. 4.

Referring to FIG. 4 and FIG. 5, the display device according to the embodiment may include a display panel 10, a driving circuit 20, a scan driving unit 30, and a power supply circuit 50.

The display device 100 of the embodiment may drive a light emitting device in an active matrix (AM) method or a passive matrix (PM) method.

The driving circuit 20 may include a data driving unit 21 and a timing control unit 22.

The display panel 10 may be formed in a rectangular shape, but is not limited thereto. That is, the display panel 10 may be formed in a circular or oval shape. At least one side of the display panel 10 may be formed to be bent at a predetermined curvature.

The display panel 10 can be divided into a display area (DA) and a non-display area (NDA) disposed around the display area (DA). The display area (DA) is an area where pixels (PX) are formed to display an image. The display panel 10 can include data lines (D1 to Dm, m is an integer greater than or equal to 2), scan lines (S1 to Sn, n is an integer greater than or equal to 2) intersecting the data lines (D1 to Dm), a high-potential voltage line (VDDL) to which a high-potential voltage is supplied, a low-potential voltage line (VSSL) to which a low-potential voltage is supplied, and pixels (PX) connected to the data lines (D1 to Dm) and the scan lines (S1 to Sn).

Each of the pixels (PX) can include a first sub-pixel (PX1), a second sub-pixel (PX2), and a third sub-pixel (PX3). The first sub-pixel (PX1) can emit a first color light of a first main wavelength, the second sub-pixel (PX2) can emit a second color light of a second main wavelength, and the third sub-pixel (PX3) can emit a third color light of a third main wavelength. The first color light can be red light, the second color light can be green light, and the third color light can be blue light, but is not limited thereto. In addition, although FIG. 4 illustrates that each of the pixels (PXs) includes three sub-pixels, the present invention is not limited thereto. That is, each of the pixels (PXs) can include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line (VDDL). The first sub-pixel (PX1) may include light emitting devices (LD), a plurality of transistors for supplying current to the light emitting devices (LD), and at least one capacitor (Cst), as shown in FIG. 5.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity-type semiconductor layers, and a second electrode. Here, the first electrode may be an anode electrode, and the second electrode may be a cathode electrode, but is not limited thereto.

The light emitting device (LD) may be one of a horizontal light emitting device, a flip-chip light emitting device, and a vertical light emitting device.

The plurality of transistors may include a driving transistor (DT) that supplies current to the light emitting devices (LD), and a scan transistor (ST) that supplies a data voltage to a gate electrode of the driving transistor (DT), as shown in FIG. 5. The driving transistor (DT) may include a gate electrode connected to a source electrode of the scan transistor (ST), a source electrode connected to a high-potential voltage line (VDDL) to which a high-potential voltage is applied, and a drain electrode connected to the first electrodes of the light emitting devices (LD). A scan transistor (ST) may include a gate electrode connected to a scan line (Sk, where k is an integer satisfying 1≤k≤n), a source electrode connected to a gate electrode of a driving transistor (DT), and a drain electrode connected to a data line (Dj, where j is an integer satisfying 1≤j≤m).

The capacitor (Cst) is formed between the gate electrode and the source electrode of the driving transistor (DT). The storage capacitor (Cst) charges the difference between the gate voltage and the source voltage of the driving transistor (DT).

The driving transistor (DT) and the scan transistor (ST) may be formed as thin film transistors. In addition, in FIG. 5, the driving transistor (DT) and the scan transistor (ST) are described mainly as being formed as P-type MOSFETs (Metal Oxide Semiconductor Field Effect Transistors), but the present invention is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

In addition, in FIG. 5, the first sub-pixel (PX1), the second sub-pixel (PX2), and the third sub-pixel (PX3) each include a 2T1C (2 Transistor-1 capacitor) having one driving transistor (DT), one scan transistor (ST), and one capacitor (Cst), but the present invention is not limited thereto. The first sub-pixel (PX1), the second sub-pixel (PX2), and the third sub-pixel (PX3) each may include a plurality of scan transistors (ST) and a plurality of capacitors (Cst).

Since the second sub-pixel (PX2) and the third sub-pixel (PX3) may be expressed in substantially the same circuit diagram as the first sub-pixel (PX1), a detailed description thereof will be omitted.

The driving circuit 20 outputs signals and voltages for driving the display panel 10. To this end, the driving circuit 20 may include a data driving unit 21 and a timing control unit 22.

The data driving unit 21 receives digital video data (DATA) and a source control signal (DCS) from the timing control unit 22. The data driving unit 21 converts digital video data (DATA) into analog data voltages according to the source control signal (DCS) and supplies them to the data lines (D1 to Dm) of the display panel 10.

The timing control unit 22 receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system-on-chip of a TV, etc.

The timing control unit 22 generates control signals for controlling the operation timing of the data driving unit 21 and the scan driving unit 30. The control signals may include a source control signal (DCS) for controlling the operation timing of the data driving unit 21 and a scan control signal (SCS) for controlling the operation timing of the scan driving unit 30.

The driving circuit 20 may be placed in a non-display area (NDA) provided on one side of the display panel 10. The driving circuit 20 may be formed as an integrated circuit (IC) and mounted on the display panel 10 using a COG (chip on glass) method, a COP (chip on plastic) method, or an ultrasonic bonding method, but the present invention is not limited thereto. For example, the driving circuit 20 may be mounted on a circuit board (not shown) rather than the display panel 10.

The data driving unit 21 may be mounted on the display panel 10 using a COG (chip on glass) method, a COP (chip on plastic) method, or an ultrasonic bonding method, and the timing control unit 22 may be mounted on a circuit board.

The scan driving unit 30 receives a scan control signal (SCS) from the timing control unit 22. The scan driving unit 30 generates scan signals according to the scan control signal (SCS) and supplies them to the scan lines (S1 to Sn) of the display panel 10. The scan driving unit 30 may include a plurality of transistors and may be formed in a non-display area (NDA) of the display panel 10. Alternatively, the scan driving unit 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, the lead lines of the circuit board may be electrically connected to the pads. The circuit board may be a flexible printed circuit board, a printed circuit board, or a flexible film such as a chip on film. The circuit board may be bent to the bottom of the display panel 10. As a result, one side of the circuit board is attached to one edge of the display panel 10, and the other side may be disposed at the bottom of the display panel 10 and connected to a system board on which a host system is mounted.

The power supply circuit 50 can generate voltages required for driving the display panel 10 from the main power applied from the system board and supply them to the display panel 10. For example, the power supply circuit 50 can generate a high-potential voltage (VDD) and a low-potential voltage (VSS) for driving the light emitting devices (LD) of the display panel 10 from the main power and supply them to the high-potential voltage line (VDDL) and the low-potential voltage line (VSSL) of the display panel 10. In addition, the power supply circuit 50 can generate and supply driving voltages for driving the driving circuit 20 and the scan driving unit 30 from the main power.

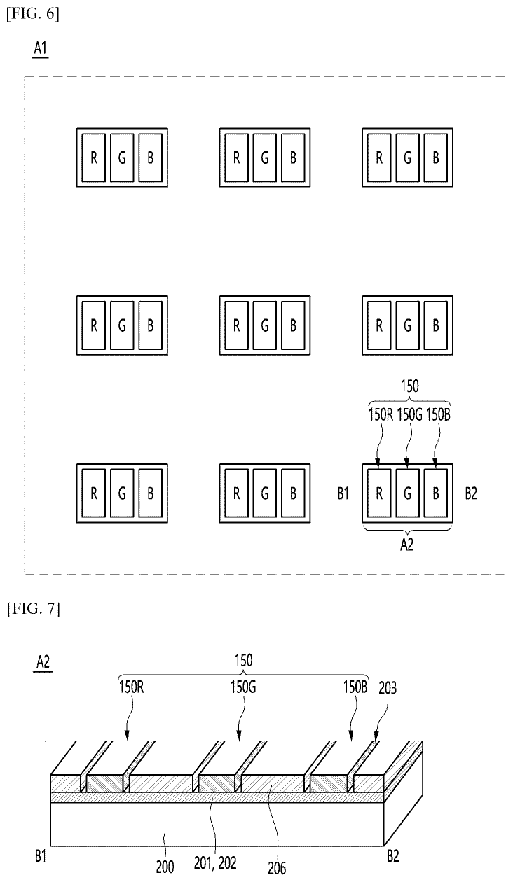

FIG. 6 is an enlarged view of the first panel area in the display device of FIG. 3.

Referring to FIG. 6, the display device 100 of the embodiment can be manufactured by mechanically and electrically connecting a plurality of panel areas, such as the first panel area (A1), by tiling.

The first panel area (A1) can include a plurality of semiconductor light emitting devices 150 disposed for each unit pixel (PX of FIG. 4).

For example, a unit pixel (PX) may include a first sub-pixel (PX1), a second sub-pixel (PX2), and a third sub-pixel (PX3). For example, a plurality of red semiconductor light emitting devices 150R may be disposed in a first sub-pixel (PX1), a plurality of green semiconductor light emitting devices 150G may be disposed in a second sub-pixel (PX2), and a plurality of blue semiconductor light emitting devices 150B may be disposed in a third sub-pixel (PX3). The unit pixel (PX) may further include a fourth sub-pixel in which no semiconductor light emitting devices are disposed, but this is not limited thereto.

FIG. 7 is an enlarged view of an area A2 of FIG. 6.

Referring to FIG. 7, the display device 100 of the embodiment may include a substrate 200, an assembly wiring 201 and 202, an insulating layer 206, and a plurality of semiconductor light emitting devices 150. There may be more components included than this.

The assembly wiring may include a first assembly wiring 201 and a second assembly wiring 202 that are spaced apart from each other. The first assembly wiring 201 and the second assembly wiring 202 may be provided to generate a dielectrophoretic force (DEP) to assemble the semiconductor light emitting device 150. For example, the semiconductor light emitting device 150 may be one of a horizontal semiconductor light emitting device, a flip-chip type semiconductor light emitting device, and a vertical semiconductor light emitting device.

The semiconductor light emitting device 150 may include a red semiconductor light emitting device 150, a green semiconductor light emitting device 150G, and a blue semiconductor light emitting device 150B to form a unit pixel (sub-pixel), but is not limited thereto, and may also include a red phosphor and a green phosphor to implement red and green, respectively.

The substrate 200 may be a supporting member that supports components placed on the substrate 200 or a protective member that protects the components.

The substrate 200 may be a rigid substrate or a flexible substrate. The substrate 200 may be formed of sapphire, glass, silicon, or polyimide. In addition, the substrate 200 may include a flexible material such as PEN (Polyethylene Naphthalate) or PET (Polyethylene Terephthalate). In addition, the substrate 200 may be a transparent material, but is not limited thereto. The substrate 200 may function as a supporting substrate in a display panel, and may also function as an assembly substrate when self-assembling a light emitting device.

The substrate 200 may be a backplane equipped with circuits, such as transistors (ST, DT), capacitors (Cst), signal wiring, etc., within the sub-pixels (PX1, PX2, PX3) illustrated in FIGS. 4 and 5, but is not limited thereto.

The substrate 200 may be a backplane equipped with circuits, such as transistors (ST, DT), capacitors (Cst), signal wiring, etc., within the sub-pixels (PX1, PX2, PX3) illustrated in FIGS. 4 and 5, but is not limited thereto.

The insulating layer 206 may include an organic material having insulation and flexibility, such as polyimide, PAC, PEN, PET, polymer, etc., or an inorganic material, such as silicon oxide (SiO2) or silicon nitride series (SiNx), and may be formed integrally with the substrate 200 to form a single substrate.

The insulating layer 206 may be a conductive adhesive layer having adhesiveness and conductivity, and the conductive adhesive layer may have flexibility to enable a flexible function of the display device. For example, the insulating layer 206 may be an anisotropic conductive film (ACF) or a conductive adhesive layer such as an anisotropic conductive medium, a solution containing conductive particles, etc. The conductive adhesive layer may be a layer that is electrically conductive in a direction vertical to the thickness, but electrically insulating in a direction horizontal to the thickness.

The insulating layer 206 may include an assembly hole 203 for inserting the semiconductor light emitting device 150. Therefore, during self-assembly, the semiconductor light emitting device 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc. For example, the red semiconductor light emitting device, the green semiconductor light emitting device, and the blue semiconductor light emitting device each have different shapes, and may have an assembly hole 203 having a shape corresponding to the shape of each of these semiconductor light emitting devices. For example, the assembly hole 203 may include a first assembly hole for assembling the red semiconductor light emitting device, a second assembly hole for assembling the green semiconductor light emitting device, and a third assembly hole for assembling the blue semiconductor light emitting device. For example, the red semiconductor light emitting device may have a circular shape, the green semiconductor light emitting device may have a first oval shape having a first short axis and a second long axis, and the blue semiconductor light emitting device may have a second oval shape having a second short axis and a second long axis, but this is not limited thereto. The second long axis of the oval shape of the blue semiconductor light emitting device may be larger than the second long axis of the oval shape of the green semiconductor light emitting device, and the second short axis of the oval shape of the blue semiconductor light emitting device may be smaller than the first short axis of the oval shape of the green semiconductor light emitting device.

The assembly hole 203 may be different depending on the shape of the semiconductor light emitting device 150. For example, the red semiconductor light emitting device, the green semiconductor light emitting device, and the blue semiconductor light emitting device each have different shapes, and may have an assembly hole 203 having a shape corresponding to the shape of each of these semiconductor light emitting devices. For example, the assembly hole 203 may include a first assembly hole for assembling the red semiconductor light emitting device, a second assembly hole for assembling the green semiconductor light emitting device, and a third assembly hole for assembling the blue semiconductor light emitting device. For example, the red semiconductor light emitting device may have a circular shape, the green semiconductor light emitting device may have a first elliptical shape having a first short axis and a second long axis, and the blue semiconductor light emitting device may have a second elliptical shape having a second short axis and a second long axis, but this is not limited thereto. The second major axis of the ellipse of the blue semiconductor light emitting device may be longer than the second major axis of the ellipse of the green semiconductor light emitting device, and the second minor axis of the ellipse of the blue semiconductor light emitting device may be shorter than the first minor axis of the ellipse of the green semiconductor light emitting device.

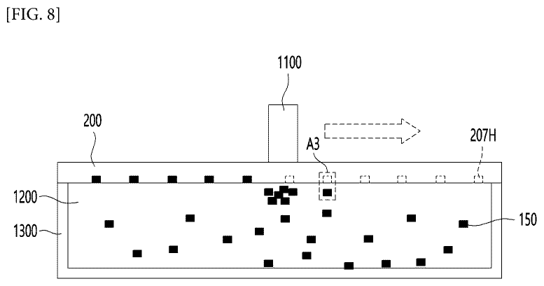

Meanwhile, the method of mounting the semiconductor light emitting device 150 on the substrate 200 may include, for example, a self-assembly method (FIG. 8) and a transfer method.

FIG. 8 is a drawing showing an example of assembling a light emitting device according to an embodiment on a substrate by a self-assembly method.

Based on FIG. 8, an example of assembling a semiconductor light emitting device according to an embodiment on a display panel by a self-assembly method using an electromagnetic field will be described.

The assembly substrate 200 described below can also function as a panel substrate 200a in a display device after assembling the light emitting device, but the embodiment is not limited thereto.

Referring to FIG. 8, the semiconductor light emitting device 150 can be introduced into a chamber 1300 filled with a fluid 1200, and the semiconductor light emitting device 150 can be moved to the assembly substrate 200 by a magnetic field generated from the assembly device 1100. At this time, the light emitting device 150 adjacent to the assembly hole 207H of the assembly substrate 200 can be assembled into the assembly hole 207H by the DEP force caused by the electric field of the assembly wirings. The fluid 1200 can be water such as ultrapure water, but is not limited thereto. The chamber can be called a tank, a container, a vessel, etc.

After the semiconductor light emitting device 150 is introduced into the chamber 1300, the assembly substrate 200 can be placed on the chamber 1300. Depending on the embodiment, the assembly substrate 200 can also be introduced into the chamber 1300.

The semiconductor light emitting device 150 may include a magnetic layer (not shown) having a magnetic substance. The magnetic layer may include a metal having magnetism, such as nickel (Ni). Since the semiconductor light emitting device 150 injected into the fluid includes a magnetic layer, it may move to the assembly substrate 200 by a magnetic field generated from the assembly device 1100. The magnetic layer may be disposed on the upper or lower side or both sides of the light emitting device.

The semiconductor light emitting device 150 may include a passivation layer surrounding the upper surface and the side surface. The passivation layer may be formed by using an inorganic insulator such as silica or alumina through PECVD, LPCVD, sputtering deposition, etc. In addition, the passivation layer may be formed by using a method of spin coating an organic material such as a photoresist or a polymer material.

The semiconductor light emitting device 150 may include a first conductivity-type semiconductor layer, a second conductivity-type semiconductor layer, and an active layer disposed therebetween. The first conductivity-type semiconductor layer may be an n-type semiconductor layer, and the second conductivity-type semiconductor layer may be a p-type semiconductor layer, but is not limited thereto. The first conductivity-type semiconductor layer, the second conductivity-type semiconductor layer, and the active layer disposed therebetween may constitute a light emitting portion. The light emitting portion may be called a light emitting layer, a light emitting region, etc.

The first electrode (layer) may be disposed under the first conductivity-type semiconductor layer, and the second electrode (layer) may be disposed on the second conductivity-type semiconductor layer. To this end, a portion of the first conductivity-type semiconductor layer or the second conductivity-type semiconductor layer may be exposed to the outside. Accordingly, after the semiconductor light emitting device 150 is assembled on the assembly substrate 200, a portion of the passivation layer may be etched in the manufacturing process of the display device.

The first electrode may include at least one layer. For example, the first electrode may include an ohmic layer, a reflective layer, a magnetic layer, a conductive layer, an anti-oxidation layer, an adhesive layer, etc. The ohmic layer may include Au, AuBe, etc. The reflective layer may include Al, Ag, etc. The magnetic layer may include Ni, Co, etc. The conductive layer may include Cu, etc. The anti-oxidation layer may include Mo, etc. The adhesive layer may include Cr, Ti, etc.

The second electrode may include a transparent conductive layer. For example, the second electrode may include ITO, IZO, etc.

The assembly substrate 200 may include a pair of first assembly wirings 201 and second assembly wirings 202 corresponding to each of the semiconductor light emitting devices 150 to be assembled. Each of the first assembly wirings 201 and the second assembly wirings 202 may be formed by multiply laminating a single metal, a metal alloy, a metal oxide, etc. For example, each of the first assembly wiring 201 and the second assembly wiring 202 may be formed by including at least one of Cu, Ag, Ni, Cr, Ti, Al, Rh, Pd, Ir, Ru, Mg, Zn, Pt, Au, and Hf, but is not limited thereto.

The first assembly wiring 201 and the second assembly wiring 202 form an electric field when an AC voltage is applied, and the semiconductor light emitting device 150 inserted into the assembly hole 207H can be fixed by the DEP force caused by the electric field. The gap between the first assembly wiring 201 and the second assembly wiring 202 can be smaller than the width of the semiconductor light emitting device 150 and the width of the assembly hole 207H, and the assembly position of the semiconductor light emitting device 150 can be fixed more precisely using the electric field.

An insulating layer 215 is formed on the first assembly wiring 201 and the second assembly wiring 202, thereby protecting the first assembly wiring 201 and the second assembly wiring 202 from the fluid 1200 and preventing leakage of current flowing in the first assembly wiring 201 and the second assembly wiring 202. For example, the insulating layer 215 may be formed of an inorganic insulator such as silica or alumina, or an organic insulator in a single layer or multiple layers. The insulating layer 215 may have a minimum thickness to prevent damage to the first assembly wiring 201 and the second assembly wiring 202 during assembly of the semiconductor light emitting device 150, and may have a maximum thickness to stably assemble the semiconductor light emitting device 150.

A barrier wall 207 may be formed on the upper portion of the insulating layer 215. Some areas of the barrier wall 207 may be located on the upper portion of the first assembly wiring 201 and the second assembly wiring 202, and the remaining areas may be located on the upper portion of the assembly substrate 200.

Meanwhile, when manufacturing the assembly board 200, some of the barrier walls formed on the upper part of the insulating layer 215 are removed, so that an assembly hole 207H in which each of the semiconductor light emitting devices 150 is coupled and assembled to the assembly board 200 can be formed.

An assembly hole 207H in which the semiconductor light emitting devices 150 are coupled is formed in the assembly board 200, and a surface on which the assembly hole 207H is formed can come into contact with a fluid 1200. The assembly hole 207H can guide the exact assembly position of the semiconductor light emitting device 150.

Meanwhile, the assembly hole 207H can have a shape and size corresponding to the shape of the semiconductor light emitting device 150 to be assembled at the corresponding position. Accordingly, it is possible to prevent another semiconductor light emitting device from being assembled in the assembly hole 207H or a plurality of semiconductor light emitting devices from being assembled.

Referring again to FIG. 8, after the assembly substrate 200 is placed in the chamber, an assembly device 1100 that applies a magnetic field can move along the assembly substrate 200. The assembly device 1100 can be a permanent magnet or an electromagnet.

Referring back to FIG. 8, after the assembly substrate 200 is placed in the chamber, the assembly device 1100 that applies a magnetic field can move along the assembly substrate 200. The assembly device 1100 can be a permanent magnet or an electromagnet.

The assembly device 1100 can move in contact with the assembly substrate 200 to maximize the area affected by the magnetic field into the fluid 1200. Depending on the embodiment, the assembly device 1100 can include a plurality of magnetic bodies or can include magnetic bodies of a size corresponding to the assembly substrate 200. In this case, the movement distance of the assembly device 1100 can be limited to a predetermined range.

The semiconductor light emitting device 150 in the chamber 1300 can move toward the assembly device 1100 and the assembly substrate 200 by the magnetic field generated by the assembly device 1100.

The semiconductor light emitting device 150 can be fixed by entering the assembly hole 207H by the DEP force formed by the electric field between the assembly wirings 201 and 202 while moving toward the assembly device 1100.

Specifically, the first and second assembly wirings 201 and 202 form an electric field by an AC power source, and a DEP force can be formed between the assembly wirings 201 and 202 by this electric field. The semiconductor light emitting device 150 can be fixed to the assembly hole 207H on the assembly board 200 by this DEP force.

At this time, a predetermined solder layer (not shown) is formed between the light emitting device 150 assembled on the assembly hole 207H of the assembly board 200 and the assembly wiring 201 and 202, thereby improving the bonding strength of the light emitting device 150.

In addition, a molding layer (not shown) can be formed in the assembly hole 207H of the assembly board 200 after assembly. The molding layer can be a transparent resin or a resin containing a reflective material or a scattering material.

Since the time required for each semiconductor light emitting device to be assembled on a substrate can be drastically shortened by the self-assembly method using the electromagnetic field described above, a large-area, high-pixel display can be implemented more quickly and economically.

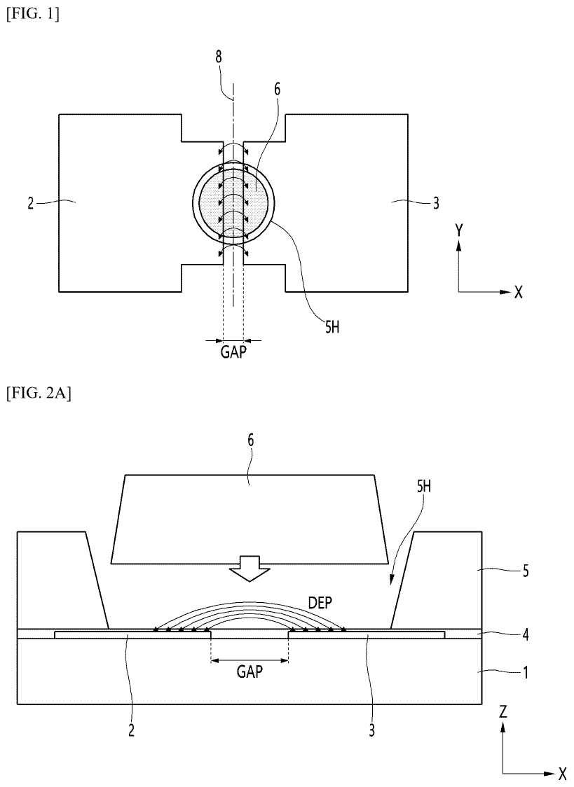

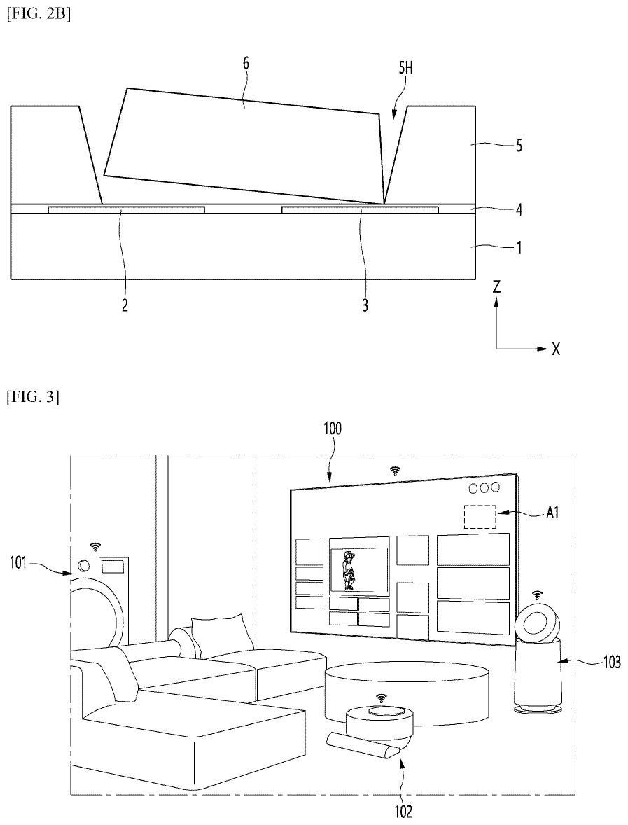

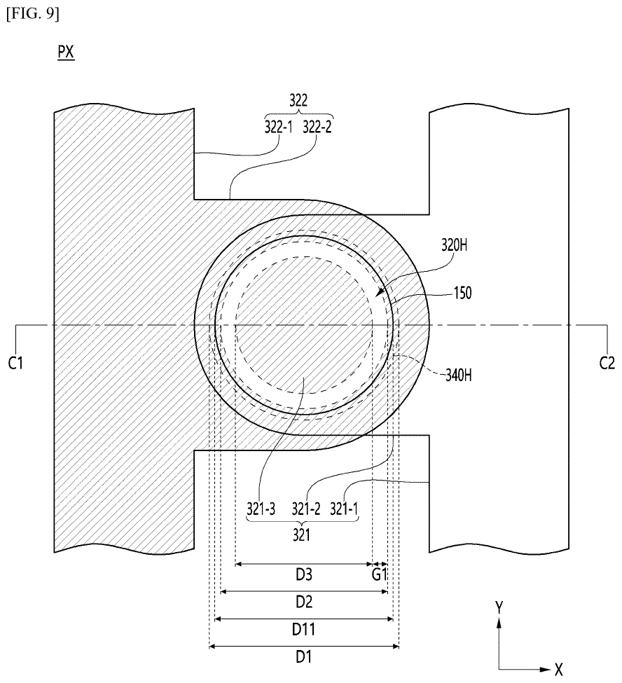

Hereinafter, various embodiments for solving the above-described problem will be described with reference to FIGS. 9 to 19. Any description omitted below can be easily understood from the description described above with respect to FIGS. 1 to 8 and the corresponding drawings.

### First Embodiment

FIG. 9 is a plan view illustrating a sub-pixel according to the first embodiment.

Referring to FIG. 9, the sub-pixel (PX) according to the first embodiment may include a first assembly wiring 321, a second assembly wiring 322, a barrier wall 340, and a semiconductor light emitting device 150.

The first assembly wiring 321 and the second assembly wiring 322 may be disposed parallel to each other. The first assembly wiring 321 and the second assembly wiring 322 may be electrodes for forming a DEP force. The semiconductor light emitting device 150 may be assembled into the first hole 340H of the barrier wall 340 by the DEP force formed between the first assembly wiring 321 and the second assembly wiring 322.

The gap between the first assembly wiring 321 and the second assembly wiring 322 may be defined as a gap (G1).

In the embodiment, the gap (G1) may be located at an edge area of the first hole 340H. For example, the gap (G1) may be located along an edge area of the first hole 340H. To this end, the second assembly wiring 322 may surround a portion of the first assembly wiring 321. For example, a portion of the first assembly wiring 321 may be located at a central area of the first hole 340H. A portion of the first assembly wiring 321 may be a protruding electrode 321-3, which will be described in detail later.

The second assembly wiring 322 may have a predetermined gap (G1) with a portion of the first assembly wiring 321 and may be disposed along an outer perimeter of a portion of the first assembly wiring 321, i.e., along an edge area of the first hole 340H. Accordingly, when the semiconductor light emitting device 150 is assembled in the first hole 340H, the gap (G1) can be positioned along the edge area of the lower side of the semiconductor light emitting device 150. In this case, a DEP force can be formed along the edge area of the first hole 340H by the AC voltage applied to the first assembly wiring 321 and the second assembly wiring 322.

Since the DEP force formed along the edge area of the first hole 340H directly affects the edge area of the lower side of the semiconductor light emitting device 150, the semiconductor light emitting device 150 can be stably assembled to the first hole 340H without shaking. In particular, since the DEP force is the largest along the edge area of the first hole 340H, the edge area of the lower side of the semiconductor light emitting device 150 is affected by the largest DEP force and is strongly pulled toward the bottom surface of the first hole 340H, so it does not twist or tilt.

Meanwhile, the second assembly wiring 322 may include the second hole 320H. The second hole 320H may be formed by penetrating the second assembly wiring 322. That is, the second hole 320H may be formed by removing a portion of the second assembly wiring 322 from the upper surface to the lower surface.

For example, the diameter (D2) of the second hole 320H may be smaller than the diameter (D1) of the first hole 340H. Accordingly, the second hole 320H may be formed within the first hole 340H. In other words, the first hole 340H may surround the second hole 320H.

The reason why the diameter (D2) of the second hole 320H is smaller than the diameter (D1) of the first hole 340H is that the protruding electrode 321-3 is disposed in the second hole 320H. That is, by arranging the protruding electrode 321-3 in the second hole 320H, the protruding electrode 321-3 can be surrounded by the second assembly wiring 322. At this time, the gap (G1) between the protruding electrode 321-3 and the second assembly wiring 322 can be positioned along the circumference of the protruding electrode 321-3. For example, the gap (G1) can form a closed loop along the circumference of the protruding electrode 321-3, but is not limited thereto.

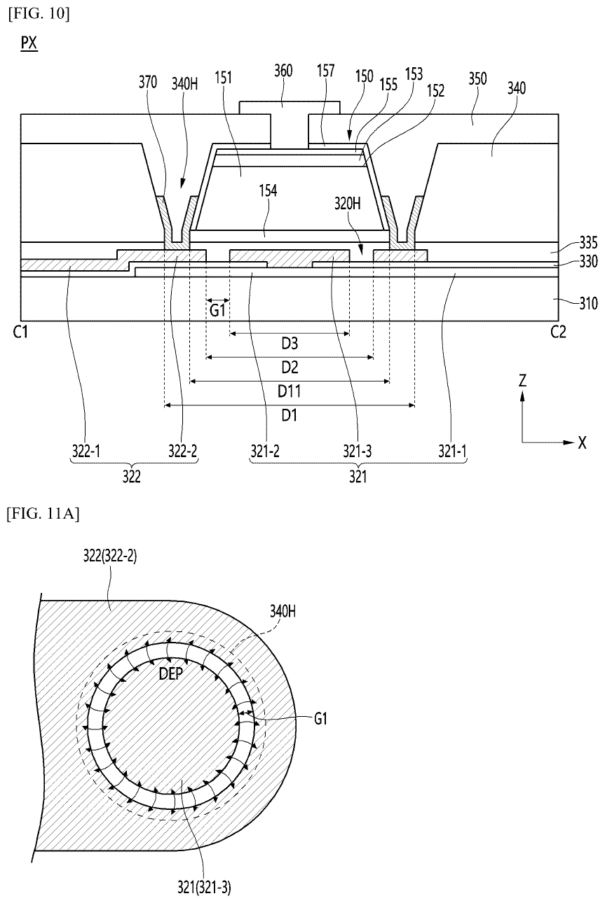

FIG. 10 is a cross-sectional view taken along the line C1-C2 of FIG. 9.

Referring to FIGS. 9 and 10, a sub-pixel (PX) according to an embodiment may include a substrate (310), a first assembly wiring 321, a second assembly wiring 322, a barrier wall 340, and a semiconductor light emitting device 150.

The substrate may be a supporting member that supports components disposed on the substrate (310) or a protective member that protects the components, and may be the substrate 200 illustrated in FIG. 7.

The first assembly wiring 321 and the second assembly wiring 322 may be disposed on the substrate. For example, the first assembly wiring 321 and the second assembly wiring 322 may be made of a metal having excellent electrical conductivity.

For example, the first assembly wiring 321 and/or the second assembly wiring 322 may include at least one reflective layer having excellent light reflectivity. In this case, light traveling downward from the semiconductor light emitting device 150 may be reflected upward, thereby improving light efficiency.

For example, the first assembly wiring 321 and the second assembly wiring 322 may each have a multilayer structure, but are not limited thereto.

The first assembly wiring 321 may include a main electrode 321-1, an extension electrode 321-2, and a protruding electrode 321-3.

The main electrode 321-1 may be disposed lengthwise along the Y direction (hereinafter referred to as the second direction). The main electrode 321-1 of the first assembly wiring 321 may be a main electrical path for supplying a first voltage supplied from the outside to each sub-pixel (PX).

The extension electrode 321-2 may be disposed along the X-axis direction (hereinafter referred to as the first direction). The extension electrode 321-2 may be disposed along the first direction in each sub-pixel (PX). For example, the extension electrode 321-2 may extend from the main electrode 321-1 toward the second assembly wiring 322. The main electrode 321-1 and the extension electrode 321-2 may be formed integrally. The main electrode 321-1 and the extension electrode 321-2 may be disposed on the same layer. The main electrode 321-1 and the extension electrode 321-2 may include the same metal. The main electrode 321-1 and the extension electrode 321-2 may be formed simultaneously by the same patterning process using the same metal.

The protruding electrode 321-3 may be electrically connected to the extension electrode 321-2. For example, the protruding electrode 321-3 may be disposed on the extension electrode 321-2. For example, the protruding electrode 321-3 may protrude in the Z direction (hereinafter, referred to as the third direction) on the extension electrode 321-2. Therefore, the protruding electrode 321-3 may be electrically connected to the extension electrode 321-2 in the vertical direction.

The protruding electrode 321-3 may not be formed integrally with the main electrode 321-1 and the extension electrode 321-2. The protruding electrode 321-3 may include a metal different from the metal included in the main electrode 321-1 and the extension electrode 321-2, but is not limited thereto. The protruding electrode 321-3 may be formed by a patterning process different from the patterning process for forming the main electrode 321-1 and the extension electrode 321-2.

For example, the protruding electrode 321-3 may include the same metal as the metal included in the second assembly wiring 322. The protruding electrode 321-3 may be disposed on the same layer as the second assembly wiring 322. The protruding electrode 321-3 and the second assembly wiring 322 can be formed simultaneously by the same patterning process using the same metal.

The first voltage applied from the first assembly wiring 321 to the main electrode 321-1 can be supplied to the protruding electrode 321-3 via the extension electrode 321-2.

Meanwhile, the second assembly wiring 322 can include the main electrode 322-1 and the auxiliary electrode 322-2.

The main electrode 322-1 may be disposed lengthwise along the second direction. The main electrode 322-1 of the second assembly wiring 322 may be disposed parallel to the main electrode 322-1 of the first assembly wiring 321. The main electrode 322-1 of the second assembly wiring 322 may be an electrical path for supplying the second voltage supplied from the outside to each sub-pixel (PX).

The first voltage may be periodically changed into a positive voltage and a negative voltage based on the second voltage, or the second voltage may be periodically changed into a positive voltage and a negative voltage based on the first voltage. Alternatively, the first voltage and the second voltage may be changed into voltages of opposite polarity to each other. For example, when the first voltage is a positive voltage, the second voltage may be a negative voltage, and when the first voltage is a negative voltage, the second voltage may be a positive voltage.

The auxiliary electrode 322-2 may be disposed along the first direction. The auxiliary electrode 322-2 may extend from the main electrode 322-1 toward the first assembly wiring 321.

The extension electrode 321-2 of the first assembly wiring 321 and the auxiliary electrode 322-2 of the second assembly wiring 322 may be disposed in the sub-pixel (PX). That is, the main electrode 322-1 of the first assembly wiring 321 may be disposed to pass through each sub-pixel (PX) disposed along the second direction, and the extension electrode 321-2 of the first assembly wiring 321 may be extended from the main electrode 322-1 in each sub-pixel (PX). The main electrode 322-1 of the second assembly wiring 322 may be disposed to pass through each sub-pixel (PX) disposed along the second direction, and the auxiliary electrode 322-2 of the second assembly wiring 322 may be extended from the main electrode 322-1 in each sub-pixel (PX).

The auxiliary electrode 322-2 and the extension electrode 321-2 of the first assembly wiring 321 may extend in opposite directions. For example, the extension electrode 321-2 may extend from the first assembly wiring 321 in the X(−) direction, and the auxiliary electrode 322-2 may extend from the second assembly wiring 322 in the X(+) direction.

The main electrode 322-1 and the auxiliary electrode 322-2 may be formed integrally. The main electrode 322-1 and the auxiliary electrode 322-2 may be disposed on the same layer. The main electrode 322-1 and the auxiliary electrode 322-2 may include the same metal. The main electrode 322-1 and the auxiliary electrode 322-2 may be simultaneously formed by the same patterning process using the same metal.

In addition, the main electrode 322-1, the auxiliary electrode 322-2, and the protruding electrode 321-3 of the first assembly wiring 321 may be disposed on the same layer. The protruding electrode 321-3 of the first cooking wiring may also include the same metal as each of the main electrode 322-1 and/or the auxiliary electrode 322-2. The main electrode 322-1, the auxiliary electrode 322-2, and the protruding electrode 321-3 of the first assembly wiring 321 may be simultaneously formed by the same patterning process using the same metal.

Meanwhile, the auxiliary electrode 322-2 of the second assembly wiring 322 may include a second hole 320H. In this case, the protruding electrode 321-3 of the first assembly wiring 321 may be placed in the second hole 320H of the auxiliary electrode 322-2. Since the protruding electrode 321-3 is placed in the second hole 320H of the auxiliary electrode 322-2, the auxiliary electrode 322-2 may surround the protruding electrode 321-3. At this time, a predetermined gap (G1) may be formed between the protruding electrode 321-3 of the first assembly wiring 321 and the auxiliary electrode 322-2 of the second assembly wiring 322. That is, the protruding electrode 321-3 of the first assembly wiring 321 and the auxiliary electrode 322-2 of the second assembly wiring 322 may be spaced apart from each other by the predetermined gap (G1).

For example, the gap (G1) may be positioned along the edge area of the first hole 340H. Accordingly, when the semiconductor light emitting device 150 is assembled into the first hole 340H, the gap (G1) may be positioned along the edge area of the lower side of the semiconductor light emitting device 150. Accordingly, a strong DEP force is formed in the gap (G1), and since the DEP force is formed as a closed loop along the edge area of the first hole 340H, a strong DEP force is applied along the edge area of the lower side of the semiconductor light emitting device 150, so that the semiconductor light emitting device 150 may be stably assembled into the first hole 340H without shaking or twisting.

The center of the second hole 320H may coincide with the center of the first hole 340H. The diameter (D2) of the second hole 320H may be smaller than the diameter (D1) of the first hole 340H. For example, the gap (G1) between the outer surface of the protruding electrode 321-3 and the inner surface of the auxiliary electrode 322-2 may be the same along the perimeter of the protruding electrode 321-3, but is not limited thereto.

The second hole 320H may correspond to the shape of the semiconductor light emitting device 150. For example, if the semiconductor light emitting device 150 is circular when viewed from above, the second hole 320H may also be circular. For example, the diameter (D11) of the semiconductor light emitting device 150 may be smaller than the diameter (D1) of the first hole 340H. For example, the diameter (D11) of the semiconductor light emitting device 150 may be equal to or larger than the diameter (D2) of the second hole 320H.

The second hole 320H may have a shape corresponding to the shape of the protruding electrode 321-3.

The protruding electrode 321-3 may have a shape corresponding to the shape of the semiconductor foot and the element. If the semiconductor light emitting device 150 is circular, the protruding electrode 321-3 may also be circular. In this case, the diameter (D3) of the protruding electrode 321-3 may be smaller than the diameter (D11) of the semiconductor light emitting device 150. Since the diameter (D3) of the protruding electrode 321-3 is smaller than the diameter (D11) of the semiconductor light emitting device 150, when a gap (G1) is formed by the gap between the protruding electrode 321-3 and the auxiliary electrode 322-2 along the circumference of the protruding electrode 321-3, this gap (G1) may be located in the edge area on the lower side of the semiconductor light emitting device 150.

Although the protruding electrode 321-3 is illustrated as having a plate shape in the drawing, it may also be configured as a plurality of branch electrodes branched from the central region or a ring electrode having a ring shape.

Meanwhile, the barrier wall 340 may be disposed on the first assembly wiring 321 and the second assembly wiring 322. The barrier wall 340 may include a first hole 340H. A first hole 340H may be formed in each sub-pixel (PX), and the first hole 340H may be formed in the barrier wall 340. For example, after a predetermined insulating film is formed on the first assembly wiring 321 and the second assembly wiring 322, the insulating film may be removed for each sub-pixel (PX), thereby forming the first hole 340H. The first hole 340H may be a through hole removed from the upper surface to the lower surface of the insulating film.

The semiconductor light emitting device 150 may be one of a red semiconductor light emitting device, a green semiconductor light emitting device, and a blue light emitting device. By arranging red semiconductor light emitting devices, green semiconductor light emitting devices, and blue semiconductor light emitting devices in adjacent sub-pixels (PX), an image can be displayed by red light, green light, and blue light emitted from each of the red semiconductor light emitting devices, green semiconductor light emitting devices, and blue semiconductor light emitting devices, respectively.

Referring again to FIGS. 9 and 10, the sub-pixel (PX) according to the embodiment can include a first insulating layer 330, a second insulating layer 335, a connection electrode 370, a third insulating layer 350, and an electrode wiring 360.

The first insulating layer 330 can be disposed on the first assembly wiring 321. The second assembly wiring 322 can be disposed on the first insulating layer 330. The second insulating layer 335 can be disposed on the second assembly wiring 322.

The first insulation layer 330 can electrically insulate the first assembly wiring 321 and the second assembly wiring 322. The second insulation layer 335 can protect the second assembly wiring 322 from contamination by external foreign substances. The second insulation layer 335 can protect the second assembly wiring 322 from corrosion by the fluid 1200 in the chamber (1300 of FIG. 8) during self-assembly.

The first insulation layer 330 and the second insulation layer 335 can be made of an insulating material. For example, the first insulation layer 330 and the second insulation layer 335 can be made of the same material. For example, the first insulation layer 330 and the second insulation layer 335 can be made of an inorganic material such as SiOx or SiNx, but are not limited thereto. For example, the first insulating layer 330 and the second insulating layer 335 may be made of different materials.

Meanwhile, the second insulating layer 335 may be made of an insulating material having a high permittivity related to the DEP force.

Meanwhile, the connecting electrode 370 may be placed in the first hole 340H. For example, the connecting electrode 370 may be placed around the semiconductor light emitting device 150 within the first hole 340H.

The connecting electrode 370 may be placed on the side of the semiconductor light emitting device 150. The connecting electrode 370 may be connected to the first electrode 154 of the semiconductor light emitting device 150. For example, the connecting electrode 370 may be connected to the side of the first electrode 154 of the semiconductor light emitting device 150.

The connection electrode 370 may be disposed along the perimeter of the semiconductor light emitting device 150 within the first hole 340H. For example, the connection electrode 370 may be disposed between the inner surface of the first hole 340H and the outer surface of the semiconductor light emitting device 150 along the perimeter of the semiconductor light emitting device 150. In this way, since the connection electrode 370 is disposed along the perimeter of the semiconductor light emitting device 150 within the first hole 340H, the barrier wall 340 and the semiconductor light emitting device 150 may be firmly fixed by the connection electrode 370, thereby enhancing the fixation.

In addition, the side of the semiconductor region 150 may be connected to the second assembly wiring 322 through the connection electrode 370. Although not shown, the side of the semiconductor light emitting device 150 may be connected to the first assembly wiring 321 through the connection electrode 370. For example, the connection electrode 370 may be connected to the first assembly wiring 321 by penetrating the second assembly wiring 322 and the first insulating layer 330.

Meanwhile, the third insulating layer 350 may be disposed on the first hole 340H and the barrier wall 340. The third insulating layer may be disposed in the first hole 340H to protect the connection electrode 370 disposed in the first hole 340H from external impact or external foreign substances. The third insulating layer 350 may be a planarization layer. That is, since the third insulating layer 350 has a flat upper surface, the electrode wiring 360 may be easily formed on the upper surface.

For example, the third insulating layer 350 may be formed of an organic material that is easy to form a thick thickness, but is not limited thereto.

Meanwhile, the electrode wiring 360 may be disposed on the third insulating layer 350. The electrode wiring 360 may be connected to the upper side of the semiconductor light emitting device 150 through the third insulating layer 350. For example, the electrode wiring 360 may be connected to the second electrode 155 of the semiconductor light emitting device 150 through the insulating layer 350. At this time, the passivation layer 157 of the semiconductor light emitting device 150 may be etched together when the third insulating layer 350 is etched to form a contact hole.

When the electrical connection process of the semiconductor light emitting device 150 is completed, the semiconductor light emitting device 150 may emit light. For example, in the semiconductor light emitting device 150, the first conductivity-type semiconductor layer 151 includes an n-type dopant and the second conductivity-type semiconductor layer 152 includes a p-type dopant, and voltage may be applied to the electrode wiring 360 and the second assembly wiring 322. In this case, current flows through the electrode wiring 360, the semiconductor light emitting device 150, the connection electrode 370, and the second assembly wiring 322, and the semiconductor light emitting device 150 may emit light due to this current.

In FIG. 9, the ends of the extension electrode 321-2 of the first assembly wiring 321 and the auxiliary electrode 322-2 of the second assembly wiring 322 are illustrated as having a round shape when viewed from above, but may also have an angular shape or other shape.

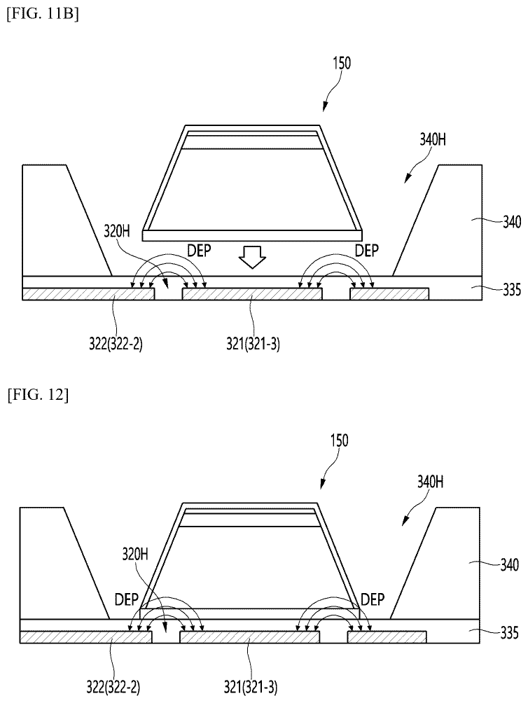

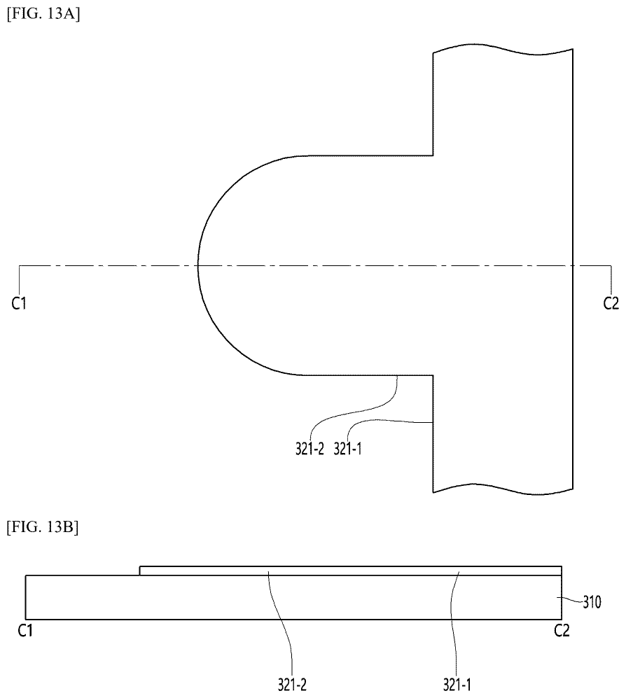

Meanwhile, a method of assembling a semiconductor light emitting device 150 is described with reference to FIGS. 11A to 12.

FIG. 11A is a plan view illustrating a state in which a DEP force is formed between a protruding electrode of a first assembly wiring and an auxiliary electrode of a second assembly wiring in a sub-pixel according to the first embodiment. FIG. 11B is a cross-sectional view illustrating a state in which a semiconductor light emitting device is assembled by a DEP force formed between a protruding electrode of a first assembly wiring and an auxiliary electrode of a second assembly wiring in a sub-pixel according to the first embodiment. FIG. 12 is a cross-sectional view illustrating a state in which a semiconductor light emitting device is assembled by a DEP force formed between a protruding electrode of a first assembly wiring and an auxiliary electrode of a second assembly wiring in a sub-pixel according to the first embodiment.

FIGS. 11A to 12 are schematically illustrated for convenience of explanation, and components omitted in FIGS. 11A to 12 can be easily understood from FIGS. 9 and 10.

As illustrated in FIGS. 9, 10, and 11b, for self-assembly, after a substrate 310 having a first hole 340H is positioned in a fluid 1200 within a chamber (1300 of FIG. 8), an AC voltage may be applied to the first assembly wiring 321 and the second assembly wiring 322. In this case, an electric field is generated between the protruding electrode 321-3 of the first assembly wiring 321 and the auxiliary electrode 322-2 of the second assembly wiring 322, and a DEP force may be formed by this electric field. As illustrated in FIG. 11A, the DEP force may be formed along the periphery of the protruding electrode 321-3. In particular, the DEP force may be formed to be the largest in the gap (G1) between the end of the protruding electrode 321-3 and the end of the auxiliary electrode 322-2.

Afterwards, the semiconductor light emitting device 150 moving in the fluid 1200 can be pulled by the DEP force formed in the first hole 340H and inserted into the first hole 340H. The edge area on the lower side of the semiconductor light emitting device 150 corresponds to the edge area of the first hole 340H, and the largest DEP force can be formed along the edge area of the first hole 340H. Accordingly, when the semiconductor light emitting device 150 is inserted into the first hole 340H, the edge area on the lower side of the semiconductor light emitting device 150 is uniformly and strongly pulled by the largest DEP force formed along the edge area in the first hole 340H, so that the semiconductor light emitting device 150 can be stably assembled into the first hole 340H.

Afterwards, as shown in FIG. 12, the semiconductor light emitting device 150 is pulled by the largest DEP force formed at the edge area of the first hole 340H, so that the semiconductor light emitting device 150 can be continuously fixed within the first hole 340H without being released out of the first hole 340H.

According to the first embodiment, a first hole 340H in which a semiconductor light emitting device 150 is assembled is provided, an auxiliary electrode 322-2 of a second assembly wiring 322 is placed in the first hole 340H, and a second hole 320H having a diameter (D2) smaller than a diameter (D1) of the first hole 340H may be formed in the auxiliary electrode 322-2.

A portion of the first assembly wiring 321 may be vertically protruded, and the auxiliary electrode 322-2 of the second assembly wiring 322 may surround the protruded portion of the first assembly wiring 321, and a predetermined gap (G1) may be formed between the portion of the first assembly wiring 321 and the auxiliary electrode 322-2 of the second assembly wiring 322. In this case, the gap (G1) may be formed along the perimeter of the protruding portion. That is, the gap (G1) may be formed along the edge area of the first hole 340H.

When an AC voltage is applied to the first assembly wiring 321 and the second assembly wiring 322 for self-assembly, the largest DEP force can be formed in the corresponding gap (G1). In this case, the largest DEP force can be formed along the edge area of the first hole 340H. The edge area of the first hole 340H can correspond to the edge area on the lower side of the semiconductor light emitting device 150 when the semiconductor light emitting device 150 is assembled within the first hole 340H.

Therefore, since the largest DEP force is applied along the edge area on the lower side of the semiconductor light emitting device 150, the semiconductor light emitting device 150 can be stably inserted into the first hole 340H without being twisted or tilted, and the semiconductor light emitting device 150 can be firmly fixed within the first hole 340H without being detached from the first hole 340H by the largest DEP force.

### Display Manufacturing Process

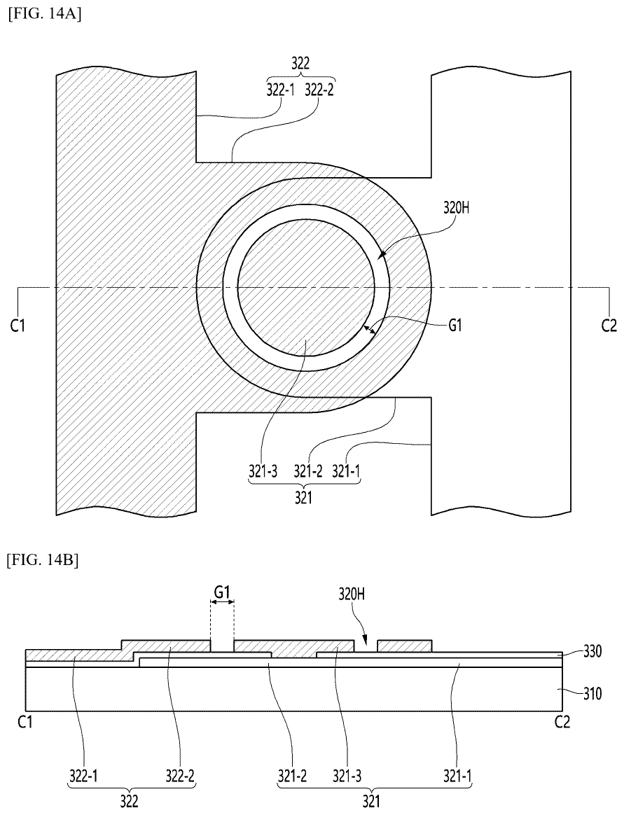

Meanwhile, a display manufacturing process according to the first embodiment will be described with reference to FIGS. 13A to 16.

FIGS. 13A and 13B illustrate a form of forming a first assembly wiring 321.

Referring to FIGS. 13A and 13B, a portion of the first assembly wiring 321 may be formed on a substrate. For example, the first assembly wiring 321 may include a main electrode 321-1 and an extension electrode 321-2 extended from the main electrode 321-1. The extension electrode 321-2 may be formed on a sub-pixel (PX of FIG. 9). For example, when a plurality of sub-pixels (PX) are disposed along one direction, a main electrode 321-1 may be formed along one direction, and an extension electrode 321-2 may be formed in each sub-pixel (PX) by extending from the main electrode 321-1.

For example, a metal film may be deposited on a substrate and the metal film may be patterned, thereby forming a first assembly wiring 321 including a main electrode 321-1 and an extension electrode 321-2 on the substrate.

Since the first assembly wiring 321 is to be serve as an electrode, it may be made of a metal having excellent electrical conductivity. In addition, the first assembly wiring 321 may be made of a metal having excellent durability to prevent corrosion. The first assembly wiring 321 may have a single-layer or multi-layer structure.

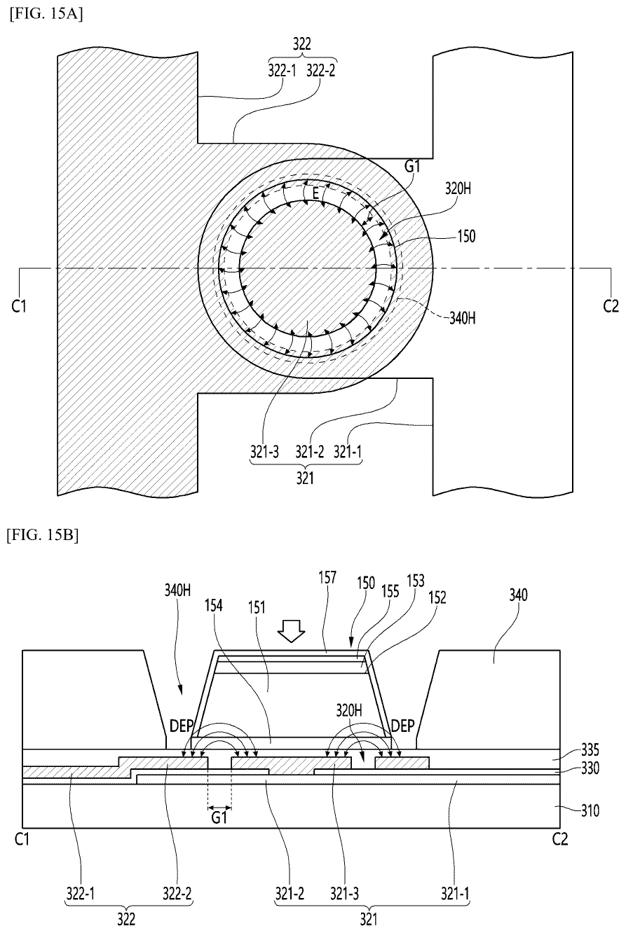

Referring to FIGS. 14A and 14B, a first insulating layer 330 may be formed on a substrate including a first assembly wiring 321. The first insulating layer 330 may be formed of an insulating material having excellent insulating properties.

Thereafter, a second assembly wiring 322 may be formed on the first insulating layer 330. For example, the second assembly wiring 322 may include a main electrode 322-1 and an auxiliary electrode 322-2 extended from the main electrode 322-1. The auxiliary electrode 322-2 may be formed in a sub-pixel (PX). For example, when a plurality of sub-pixels (PX) are disposed along one direction, a main electrode 322-1 may be formed along one direction, and an auxiliary electrode 322-2 may be extended from the main electrode 322-1 and formed in each sub-pixel (PX).

The main electrode 321-1 of the first assembly wiring 321 and the main electrode 322-1 of the second assembly wiring 322 are disposed in different layers and do not vertically overlap each other. The main electrode 321-1 of the first assembly wiring 321 and the main electrode 322-1 of the second assembly wiring 322 may be disposed parallel to each other along one direction.

The extension electrode 321-2 of the first assembly wiring 321 and the auxiliary electrode 322-2 of the second assembly wiring 322 may be disposed in different layers and may vertically overlap each other in the sub-pixel (PX). That is, in the sub-pixel (PX), an extension electrode 321-2 may be placed under the first insulating layer 330 of the first assembly wiring 321, and an auxiliary electrode 322-2 of the second assembly wiring 322 may be placed on the first insulating layer 330.

Meanwhile, the auxiliary electrode 322-2 of the second assembly wiring 322 may include a second hole 320H. The second hole 320H may be formed in the first hole (340H of FIG. 15b) to be formed later. For example, the first hole 340H may surround the second hole 320H.

A protruding electrode 321-3 may be placed on the first insulating layer 330. For example, the protruding electrode 321-3 may be formed in the second hole 320H of the auxiliary electrode 322-2. For example, the auxiliary electrode 322-2 may surround the protruding electrode 321-3.

At this time, the inner surface of the auxiliary electrode 322-2 and the outer surface of the protruding electrode 321-3 may be spaced apart from each other. The distance between the inner surface of the auxiliary electrode 322-2 and the outer surface of the protruding electrode 321-3 may be defined as a predetermined gap (G1).

Since the semiconductor light emitting device 150 is to be inserted into the first hole 340H, the first hole 340H may have a shape corresponding to the shape of the semiconductor light emitting device 150. Since the second hole 320H is to be form a corresponding gap (G1) corresponding to the edge area on the lower side of the semiconductor light emitting device 150, it may have a shape corresponding to the shape of the semiconductor light emitting device 150. For example, if the semiconductor light emitting device 150 is circular when viewed from above, the first hole 340H and the second hole 320H may each be circular.

Depending on the size of the corresponding gap (G1), the size of the DEP force formed in the corresponding gap (G1) may vary. According to an embodiment, a corresponding gap (G1) is formed along the circumference of the protruding electrode 321-3, and the size of the gap (G1) may be constant along the circumference of the protruding electrode 321-3. Accordingly, the protruding electrode 321-3 may have a shape corresponding to the shape of the second hole 320H. For example, when the second hole 320H has a circular shape, the protruding electrode 321-3 may also have a circular shape.

Meanwhile, the protruding electrode 321-3 may penetrate the first insulating layer 330 and be connected to the extension electrode 321-2 of the first assembly wiring 321. For example, the protruding electrode 321-3 and the extension electrode 321-2 of the first assembly wiring 321 may be vertically overlapped. For example, the size (or diameter) of the protruding electrode 321-3 may be smaller than the size of the extension electrode 321-2 of the first assembly wiring 321, but is not limited thereto.

The protruding electrode 321-3 may be disposed on the same layer as the main electrode 322-1 and the auxiliary electrode 322-2 of the second assembly wiring 322. That is, the main electrode 322-1 and the auxiliary electrode 322-2 of the second assembly wiring 322 and the protruding electrode 321-3 may be formed on the first insulating layer 330. For example, the main electrode 322-1 and the auxiliary electrode 322-2 of the second assembly wiring 322 and the protruding electrode 321-3 may be formed simultaneously by the same process using the same metal.

For example, after the first insulating layer 330 is formed on the substrate, a portion of the first insulating layer 330 corresponding to the extension electrode 321-2 of the first assembly wiring 321 may be removed to form a through hole. Thereafter, a metal film may be deposited on the first insulating layer 330 and then patterned, thereby forming the main electrode 322-1 and auxiliary electrode 322-2 of the second assembly wiring 322 and the protruding electrode 321-3. At this time, the protruding electrode 321-3 may be connected to the extension electrode 321-2 of the first assembly wiring 321 through the through hole formed in the first insulating layer 330.

Referring to FIG. 15a and FIG. 15b, a second insulating layer 335 may be formed on a first insulating layer 330 including a second assembly wiring 322, and a barrier wall 340 may be formed on the second insulating layer 335.

The second insulating layer 335 may be formed to protect the second assembly wiring 322. The second insulating layer 335 may be formed of an insulating material having a dielectric constant to increase the DEP force.

The barrier wall 340 and the second insulating layer 335 may be formed of different materials, but are not limited thereto.

Afterwards, the barrier wall 340 corresponding to the auxiliary electrode 322-2 of the second assembly wiring 322 in the sub-pixel (PX) may be removed, thereby forming the first hole 340H. That is, the first hole 340H may be formed by removing the barrier wall 340 corresponding to the auxiliary electrode 322-2 of the second assembly wiring 322 so that the upper surface of the second insulating layer 335 is exposed.

In this way, the substrate on which the first hole 340H is formed may be mounted in a chamber (1300 of FIG. 8) for self-assembly. At this time, the barrier wall 340 or the first hole 340H may come into contact with the fluid.

Afterwards, when an AC voltage is applied to the first assembly wiring 321 and the second assembly wiring 322, a DEP force may be formed between the protruding electrode 321-3 of the first assembly wiring 321 and the auxiliary electrode 322-2 of the second assembly wiring 322 along the edge area of the first hole 340H. At this time, the largest DEP force may be formed between the end of the protruding electrode 321-3 of the first assembly wiring 321 and the end of the auxiliary electrode 322-2 of the second assembly wiring 322. Accordingly, the semiconductor light emitting device 150 moving in the fluid may pass through the first hole 340H and be inserted into the first hole 340H by the DEP force formed along the edge area of the first hole 340H. At this time, the DEP force is applied along the edge area of the lower side of the semiconductor light emitting device 150, so that the semiconductor light emitting device 150 is pulled to the bottom of the first hole 340H and can be firmly fixed to the first hole 340H continuously by the DEP force.

After that, the substrate can be detached from the chamber and a drying process can be performed.

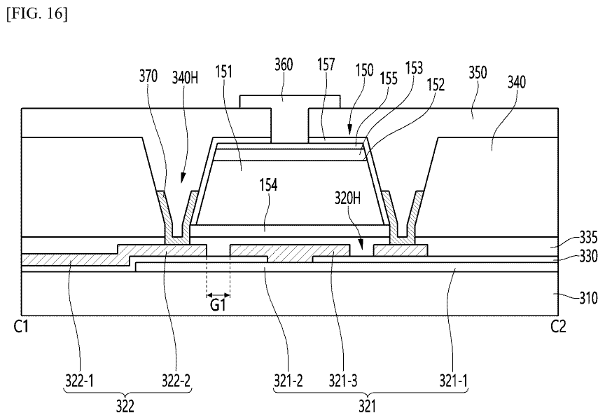

Referring to FIG. 16, the second insulating layer 335 may be removed within the first hole 340H. By removing the second insulating layer 335, the upper surface of the auxiliary electrode 322-2 of the second assembly wiring 322 may be exposed.

Thereafter, a metal film may be deposited and patterned on the barrier wall 340 including the first hole 340H, so that a connection electrode 370 may be formed along the periphery of the semiconductor light emitting device 150 within the first hole 340H. The side of the semiconductor light emitting device 150, that is, the side of the first electrode 154, and the auxiliary electrode 322-2 of the second assembly wiring 322 may be electrically connected by the connection electrode 370.

Thereafter, a third insulating layer can be formed on the semiconductor light emitting device 150 and the barrier wall 340. Thereafter, the barrier wall 340 can be removed so that the upper side of the semiconductor light emitting device 150 is exposed, thereby forming a contact hole. In addition, a passivation layer 157 of the semiconductor light emitting device 150 corresponding to the contact hole of the third insulating layer can be removed.

Afterwards, a metal film may be deposited and patterned on the third insulating layer, thereby forming an electrode wiring 360. The electrode wiring 360 may penetrate the third insulating layer and be electrically connected to the second electrode 155 of the semiconductor light emitting device 150.

### Display Device

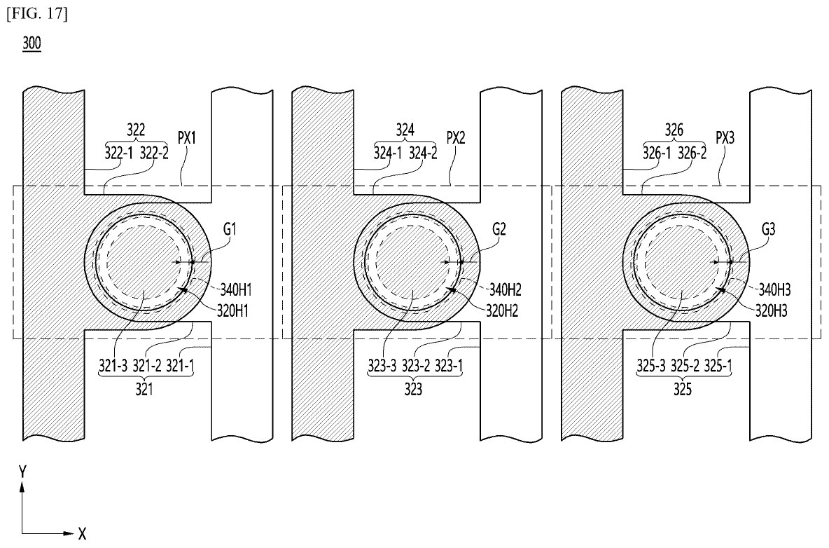

FIG. 17 is a plan view illustrating a display device according to the first embodiment. Although the electrical connections of the semiconductor light emitting devices 150-1, 150-2, and 150-3 are not illustrated in FIG. 17, these electrical connections are the same as the electrical connections illustrated in FIG. 10, and thus can be easily understood from FIG. 10.

Referring to FIG. 17, the display device (300) according to the embodiment may be equipped with a plurality of sub-pixels (PX1, PX2, PX3). In FIG. 17, only three sub-pixels (PX1, PX2, PX3) are typically provided, but multiple sub-pixels may be disposed in a matrix.

For example, a single pixel may be defined by three sub-pixels (PX1, PX2, PX3). A color image may be implemented by a unit pixel. The first to third sub-pixels (PX1, PX2, PX3) within the unit pixel may be disposed along one direction or adjacent to each other.

Although not shown, the unit pixel may include a fourth sub-pixel, and a semiconductor light emitting device may not be disposed in the fourth sub-pixel.

Therefore, a large-area image can be displayed by arranging multiple unit pixels in a matrix.

For example, a first semiconductor light emitting device 150-1 can be disposed in a first sub-pixel (PX1), a second semiconductor light emitting device 150-2 can be disposed in a second sub-pixel (PX2), and a third semiconductor light emitting device 150-3 can be disposed in a third sub-pixel (PX3).

For example, the first semiconductor light emitting device 150-1 can emit first light, i.e., red light, the second semiconductor light emitting device 150-2 can emit second light, i.e., green light, and the third semiconductor light emitting device 150-3 can emit third light, i.e., blue light. Accordingly, an image can be displayed by the red light of the first semiconductor light emitting device 150-1, the green light of the second semiconductor light emitting device 150-2, and the blue light of the third semiconductor light emitting device 150-3.

As illustrated in FIG. 17, the first sub-pixel (PX1) may include a first assembly wiring 321, a second assembly wiring 322, a first hole 340H1, and a first semiconductor light emitting device 150-1. The second sub-pixel (PX2) may include a first assembly wiring 323, a second assembly wiring (324), a first hole 340H2, and a second semiconductor light emitting device 150-2. The third sub-pixel (PX3) may include a first assembly wiring (325), a second assembly wiring 326, a first hole 340H3, and a third semiconductor light emitting device 150-3.

The first assembly wiring 321, 323, and 325 may include a main electrode (321-1, 323-1, 325-1), an extension electrode 321-2, 323-2, and 325-2 extended from the main electrode (321-1, 323-1, 325-1), and a protruding electrode 321-3, 323-3, and 325-3 protruding upward from the extension electrode 321-2, 323-2, and 325-2.

The second assembly wiring 322, 324, and 326 may include a main electrode 322-1, 324-1, and 326-1 and an auxiliary electrode 322-2, 324-2, and 326-2 extended from the main electrode 322-1, 324-1, and 326-1.

For example, the extension electrodes 321-2, 323-2, and 325-2 of the first assembly wiring 321, 323, and 325 and the auxiliary electrodes 322-2, 324-2, and 326-2 of the second assembly wiring 322, 324, and 326 may be vertically overlapped. For example, the protruding electrodes 321-3, 323-3, and 325-3 of the first assembly wiring 321, 323, and 325 and the main electrodes 322-1, 324-1, and 326-1 and the auxiliary electrodes 322-2, 324-2, and 326-2 of the second assembly wiring 322, 324, and 326 may be disposed on the same layer. For example, the protruding electrodes 321-3, 323-3, and 325-3 of the first assembly wiring 321, 323, and 325 and the main electrodes 322-1, 324-1, and 326-1 and auxiliary electrodes 322-2, 324-2, and 326-2 of the second assembly wiring 322, 324, and 326 may include the same metal. For example, the protruding electrodes 321-3, 323-3, and 325-3 of the wiring may be electrically connected to the extension electrodes 321-2, 323-2, and 325-2 of the first assembly wiring 321, 323, and 325.

The auxiliary electrodes 322-2, 324-2, and 326-2 of the second assembly wiring 322, 324, and 326 include second holes 320H1, 320H2, and 320H3, and the protruding electrodes 321-3, 323-3, and 325-3 of the first assembly wiring 321, 323, and 325 can be disposed in the second holes 320H1, 320H2, and 320H3. At this time, the auxiliary electrodes 322-2, 324-2, and 326-2 can surround the protruding electrodes 321-3, 323-3, and 325-3. For example, a predetermined gap (G1, G2, G3) may be formed between the protruding electrode 321-3, 323-3, and 325-3 and the auxiliary electrode 322-2, 324-2, and 326-2 along the periphery of the protruding electrode 321-3, 323-3, and 325-3.

When an AC voltage is applied to the first assembly wiring 321, 323, and 325 and the second assembly wiring 322, 324, and 326 of each of the first sub-pixel (PX1), the second sub-pixel (PX2), and the third sub-pixel (XP3), a DEP force can be formed along the edge area of the first hole 340H1, 340H2 , and 340H3, that is, along the perimeter of the protruding electrode 321-3, 323-3, and 325-3 of the first assembly wiring 321, 323, and 325. Accordingly, the first semiconductor light emitting device 150-1, the second semiconductor light emitting device 150-2, and the third semiconductor light emitting device 150-3 can be assembled into the first hole 340H1 of the first sub-pixel (PX1), the first hole 340H2 of the second sub-pixel (PX2), and the first hole 340H3 of the third sub-pixel (PX3), respectively.

The first semiconductor light emitting device 150-1, the second semiconductor light emitting device 150-2, and the third semiconductor light emitting device 150-3 can be sequentially assembled into the first hole 340H1 of the first sub-pixel (PX1), the first hole 340H2 of the second sub-pixel (PX2), and the first hole 340H3 of the third sub-pixel (PX3).

For example, the first semiconductor light emitting device 150-1 can be assembled into the first hole 340H1 of the first sub-pixel (PX1) by the DEP force formed by the AC voltage applied to the first assembly wiring 321 and the second assembly wiring 322 of the first sub-pixel (PX1). Thereafter, the second semiconductor light emitting device 150-2 can be assembled into the first hole 340H2 of the second sub-pixel (PX2) by the DEP force formed by the AC voltage applied to the first assembly wiring 323 and the second assembly wiring 324 of the second sub-pixel (PX2). Thereafter, the third semiconductor light emitting device 150-3 can be assembled into the first hole 340H3 of the third sub-pixel (PX3) by the DEP force formed by the AC voltage applied to the first assembly wiring 325 and the second assembly wiring 326 of the third sub-pixel (PX3).

Although not shown, the first semiconductor light emitting device 150-1, the second semiconductor light emitting device 150-2, and the third semiconductor light emitting device 150-3 may be provided so that the shapes and sizes of the first holes 340H1, 340H2, and 340H3 of the first sub-pixel (PX1), the second sub-pixel (PX2), and the third sub-pixel (PX3) are different, and the shapes correspond to the shapes and sizes of the first holes 340H1, 340H2, and 340H3 of the first sub-pixel (PX1), the second sub-pixel (PX2), and the third sub-pixel (PX3).

In this case, the first semiconductor light emitting device 150-1, the second semiconductor light emitting device 150-2, and the third semiconductor light emitting device 150-3 can be simultaneously assembled into the first sub-pixel (PX1), the second sub-pixel (PX2), and the third sub-pixel (PX3) by the same self-assembly process, respectively. That is, by the AC voltage applied to the first assembly wiring 321, 323, and 325 and the second assembly wiring 322, 324, and 326 of the first sub-pixel (PX1), the second sub-pixel (PX2), and the third sub-pixel (PX3), the DEP force can be simultaneously formed in the first hole 340H1 of the first sub-pixel (PX1), the first hole 340H2 of the second sub-pixel (PX2), and the first hole 340H3 of the third sub-pixel (PX3).

That is, even if the first semiconductor light emitting device 150-1, the second semiconductor light emitting device 150-2, and the third semiconductor light emitting device 150-3 are mixed in the fluid (1200 of FIG. 8), the first semiconductor light emitting device 150-1 can be assembled into the first hole 340H1 of the first sub-pixel (PX1) having a size corresponding to the size of the first semiconductor light emitting device 150-1, the second semiconductor light emitting device 150-2 can be assembled into the first hole 340H2 of the second sub-pixel (PX2) having a size corresponding to the size of the second semiconductor light emitting device 150-2, and the third semiconductor light emitting device 150-3 can be assembled into the first hole 340H3 of the third sub-pixel (PX3) having a size corresponding to the size of the third semiconductor light emitting device 150-3.

### Second Embodiment

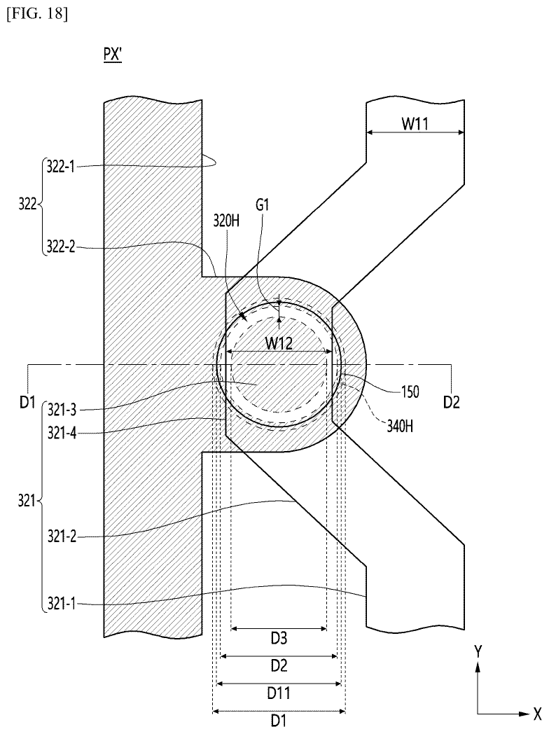

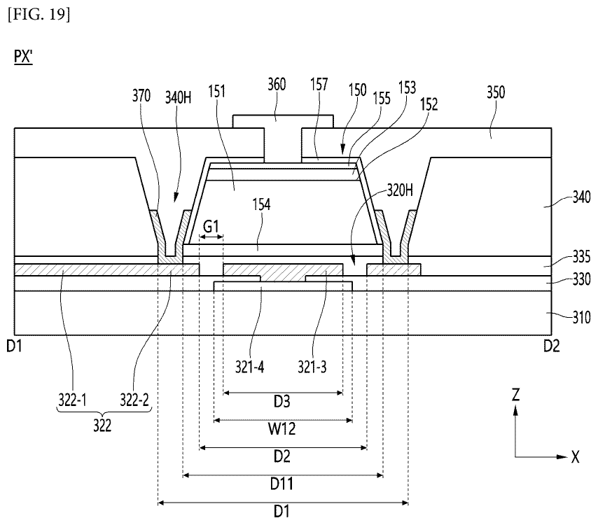

FIG. 18 is a plan view illustrating a sub-pixel according to the second embodiment. FIG. 19 is a cross-sectional view taken along the D1-D2 line of FIG. 18.

The second embodiment can reduce the vertical overlapping area of the first assembly wiring 321 and the second assembly wiring 322, thereby reducing the capacity of the parasitic capacitance. Accordingly, the second embodiment is similar to the first embodiment (FIGS. 9 and 10) except for the bending portion 321-4 provided in the first assembly wiring 321. In the second embodiment, components having the same shape, structure, and function as those in the first embodiment are given the same drawing reference numerals and detailed descriptions are omitted.

Referring to FIG. 18 and FIG. 19, the sub-pixel (PX′) according to the second embodiment may include a first assembly wiring 321, a second assembly wiring 322, a barrier wall 340, and a semiconductor light emitting device 150.

Since the structures of each of the second assembly wiring 322, the barrier wall 340, and the semiconductor light emitting device 150 have been described in the first embodiment, a detailed description thereof will be omitted.

The first assembly wiring 321 may include a main electrode 321-1, an extension electrode 321-2, a bending portion 321-4, and a protruding electrode 321-3.

The extension electrode 321-2 may extend from the main electrode 321-1 toward the sub-pixel (PX'). The bending portion may extend from the extension electrode 321-2 and be disposed in the first hole 340H of the sub-pixel (PX′).

The extension electrode 321-2 may be included in the bending portion, or the bending portion may be included in the extension electrode 321-2.

For example, the bending portion may extend from the main electrode 321-1 toward the second assembly wiring 322 in the pixel area. The extension electrodes 321-2 may be disposed at both ends of the bending portion, and each of the extension electrodes 321-2 may be connected to the main electrode 321-1. In other words, the extension electrode 321-2 may be bent toward the sub-pixel (PX′) at two points of the main electrode 321-1, and each of the bent extension electrodes 321-2 may meet at the first electrode 154 of the sub-pixel (PX′) to form a bend. In this case, the width of the bend may be equal to or smaller than the width of the extension electrode 321-2.

The width (W12) of the bend may be smaller than the width (W11) of the main electrode 321-1. For example, the width (W12) of the bend may be ⅓ or less of the width (W11) of the main electrode 321-1. In this way, as the width (W12) of the bend may be reduced, the vertical overlapping area between the auxiliary electrode 322-2 of the second assembly wiring 322 of the bend may be reduced.

For example, the width (W12) of the bending portion may be smaller than the width of the auxiliary electrode 322-2 of the second assembly wiring 322. At this time, the width of the auxiliary electrode 322-2 may mean the horizontal width or the vertical width. The horizontal width may be the width along the X direction, and the vertical width may be the width along the Y direction. Accordingly, some areas of the auxiliary electrode 322-2 of the second assembly wiring 322 may vertically overlap with the bending portion of the first assembly wiring 321, and other areas may not vertically overlap with the bending portion of the first assembly wiring 321.

For example, the width (W12) of the bending portion may be smaller than the diameter (D1) of the first hole 340H. For example, the width (W12) of the bending portion may be smaller than the diameter (D2) of the second hole 320H. For example, the width (W12) of the bending portion may be larger than the diameter (D3) of the protruding electrode 321-3 of the first assembly wiring 321, but may also be smaller than the diameter (D3) of the protruding electrode 321-3.

For example, the protruding portion may be connected to the bending portion through the first insulating layer 330.

For example, the protrusion may be connected to the bending portion through the first insulating layer 330.

By the structure of the bending portion of the first assembly wiring 321 as described above, the vertical overlapping area between the first assembly wiring 321 and the second assembly wiring 322 is reduced, thereby reducing the capacity of the parasitic capacitance. By reducing the capacity of the parasitic capacitance, the loss caused by the parasitic capacitance of the AC voltage between the first assembly wiring 321 and the second assembly wiring 322 can be reduced. Accordingly, a sufficiently large DEP force can be formed even with a smaller AC voltage, thereby reducing power consumption.

Meanwhile, the display device described above may be a display panel. That is, in the embodiment, the display device and the display panel may be understood to have the same meaning. In an embodiment, a display device in a practical sense may include a display panel and a controller (or processor) capable of controlling the display panel to display an image.

The above detailed description should not be construed as restrictive in all respects but should be considered as illustrative. The scope of the embodiments should be determined by a reasonable interpretation of the appended claims, and all changes within the equivalency range of the embodiments are intended to be included within the scope of the embodiments.

### INDUSTRIAL APPLICABILITY

The embodiment can be adopted in the field of displays that display images or information. The embodiment can be adopted in the field of displays that display images or information using semiconductor light emitting devices. The semiconductor light emitting devices can be micro-level semiconductor light emitting devices or nano-level semiconductor light emitting devices.

For example, the embodiment can be adopted in TVs, signage, smart phones, mobile phones, mobile terminals, HUDs for automobiles, backlight units for laptops, and display devices for VR or AR.

1. A display device comprising:
a substrate including a sub-pixel;
a first assembly wiring disposed along a direction on the substrate;
a second assembly wiring disposed parallel to the first assembly wiring;
a barrier wall disposed on the first assembly wiring and the second assembly wiring, and comprising a first hole in the sub-pixel; and
a semiconductor light emitting device in the first hole,
wherein the second assembly wiring is configured to surround a portion of the first assembly wiring, and
wherein the portion of the first assembly wiring and the second assembly wiring comprise a predetermined gap in an edge area of the first hole.

2. The display device according to claim 1, wherein the gap is located along the edge area on a lower side of the semiconductor light emitting device.

3. The display device according to claim 1, further comprising an insulating layer on the first assembly wiring, and
wherein the second assembly wiring is disposed on the insulating layer.

4. The display device according to claim 3, wherein the second assembly wiring comprises a main electrode and an auxiliary electrode extending from the main electrode in the sub-pixel, and
wherein the auxiliary electrode comprises a second hole comprising a diameter smaller than a diameter of the first hole.

5. The display device according to claim 4, wherein the second hole comprises a shape corresponding to a shape of the semiconductor light emitting device.

6. The display device according to claim 4, wherein the first assembly wiring comprises a main electrode and a protruding electrode in the second hole of the auxiliary electrode.

7. The display device according to claim 6, wherein the protruding electrode is connected to the main electrode through the insulating layer.

8. The display device according to claim 6, wherein the auxiliary electrode is configured to surround the protruding electrode.

9. The display device according to claim 6, wherein a diameter of the protruding electrode is smaller than a diameter of the semiconductor light emitting device.

10. The display device according to claim 6, wherein the protruding electrode and the auxiliary electrode comprise gap, and
wherein the gap is located along the edge area on a lower side of the semiconductor light emitting device.

11. The display device according to claim 6, wherein the protruding electrode comprises the same metal as the second assembly wiring.

12. The display device according to claim 6, wherein the first assembly wiring comprises a bending portion extending from the main electrode toward the second assembly in the pixel area.

13. The display device according to claim 12, wherein protruding electrode is connected to the bending portion through the insulating layer.

14. The display device according to claim 12, wherein a width of the bending portion is smaller than a width of the main electrode.

15. The display device according to claim 12, wherein a width of bending portion is smaller than the diameter of the first hole.

16. The display device according to claim 12, wherein the width of the bending portion is greater than or equal to a diameter of the protruding electrode.

17. The display device according to claim 1, further comprising a connecting electrode surrounding the semiconductor light emitting device within the first hole and an electrode wiring on the semiconductor light emitting device,
wherein the connecting electrode is connected to at least one of the first assembly wiring or the second assembly wiring.
